(19) United States
(12) Patent Application Publication
(10) Pub. No.: US 2026/0371617 A1
(43) Pub. Date: Nov. 19, 2026

(54) DEVICE INCLUDING HETEROGENEOUS MEMORY CHIPS

(71) Applicant: Samsung Electronics Co., Ltd., Suwon-si (KR)

(72) Inventors: Yonghyuk Choi, Suwon-si (KR); Seunghwan Song, Suwon-si (KR); Wandong Kim, Suwon-si (KR)

(73) Assignee: Samsung Electronics Co., Ltd., Suwon-si (KR)

(21) Appl. No.: 19/676,029

(22) Filed: May 13, 2026

(30) Foreign Application Priority Data
May 14, 2025 (KR) 10-2025-0062732
Oct. 30, 2025 (KR) 10-2025-0160298

(51) Int. Cl. H10B 80/00; H10W 90/00; H10W 90/20; H10W 90/24

(52) U.S. Cl. CPC H10B 80/00; H10W 90/24; H10W 90/297; H10W 90/752

(57) ABSTRACT

A device includes heterogeneous memory chips, which includes a first memory chip and a second memory chip. The first memory chip includes memory planes and data pad sets corresponding to respective memory planes. The data pad sets of the first memory chip include a first data pad set. The second memory chip includes a second data pad set, which is electrically connected to the first data pad set of the first memory chip. The data pad sets of the first memory chip include at least one data pad set insulated from the second memory chip, such as an internal circuit of the second memory chip. Such techniques enable a host accessing the device to perform both tasks requiring high bandwidth and tasks requiring high capacity.

### CROSS-REFERENCE TO RELATED APPLICATIONS

This present application claims priority to and the benefit under 35 U.S.C. § 119(a)-(d) of Korean Patent Application No. 10-2025-0062732, filed on May 14, 2025, in the Korean Intellectual Property Office, and Korean Patent Application No. 10-2025-0160298, filed on Oct. 30, 2025, in the Korean Intellectual Property Office, the entire disclosures of which are incorporated herein by reference.

### BACKGROUND

### 1. Field

Example embodiments relate to semiconductor memory device, and more particularly, to a device including heterogeneous memory chips, and to a method performed by a semiconductor memory device.

### 2. Description of the Related Art

A memory device may store data for various applications and may update or output stored data in response to received commands. For example, a memory device may store data in response to a write command and may output stored data in response to a read command. Depending on the application, a memory device may have a structure that provides high bandwidth or a structure that provides high capacity.

### SUMMARY

According to aspects, a device includes a first memory chip including a plurality of memory planes and a plurality of data pad sets corresponding to the plurality of memory planes, respectively, the plurality of data pad sets comprising a first data pad set, and a second memory chip including a second data pad set electrically connected to the first data pad set. The plurality of data pad sets include at least one data pad set insulated from the second memory chip.

According to aspects, a device includes a first memory chip including a plurality of memory planes and a plurality of data pad sets, each corresponding to a respective one of the plurality of memory planes, and a second memory chip including a first data pad set insulated from the plurality of data pad sets. Each of the plurality of memory planes includes a first memory cell configured to store at least one bit, and the second memory chip includes a second memory cell configured to store more bits than the at least one bit.

According to aspects, a device includes a first memory chip including a plurality of memory planes and a plurality of data pad sets, each corresponding to a respective one of the plurality of memory planes, and a second memory chip including a second data pad set electrically connected to a first data pad set of the plurality of data pad sets. The first memory chip is configured to receive or output data through the plurality of data pad sets in a first mode and to float the first data pad set in a second mode, and the second memory chip is configured to float the second data pad set in the first mode and to receive or output data through the second data pad set in the second mode.

### BRIEF DESCRIPTION OF THE DRAWINGS

These and/or other aspects, features, and advantages of the disclosure will become apparent and more readily appreciated from the following description of example embodiments, taken in conjunction with the accompanying drawings of which:

FIG. 1 is a block diagram illustrating a storage device according to example embodiments of the present disclosure;

FIGS. 2A and 2B are block diagrams illustrating examples of memory according to example embodiments of the present disclosure;

FIG. 3 is a circuit diagram illustrating a memory block according to example embodiments of the present disclosure;

FIGS. 4A, 4B, and 4C are diagrams illustrating distributions of memory cells according to example embodiments of the present disclosure;

FIGS. 5A and 5B are block diagrams illustrating examples of a memory device according to example embodiments of the present disclosure;

FIGS. 6A, 6B, 6C, and 6D are diagrams illustrating examples of a device according to example embodiments of the present disclosure;

FIG. 7 is a block diagram illustrating a memory device according to example embodiments of the present disclosure;

FIGS. 8A and 8B are block diagrams illustrating examples of a memory device according to example embodiments of the present disclosure;

FIGS. 9A, 9B, and 9C are diagrams illustrating examples of a device according to example embodiments of the present disclosure;

FIG. 10 is a timing diagram illustrating an operation of a memory device according to example embodiments of the present disclosure;

FIGS. 11A and 11B are message flow diagrams illustrating examples of operations of a memory device according to example embodiments of the present disclosure;

FIG. 12 is a diagram illustrating a device according to example embodiments of the present disclosure;

FIG. 13 is a block diagram illustrating a system according to example embodiments of the present disclosure; and

FIG. 14 is a block diagram illustrating a system according to example embodiments of the present disclosure.

### DETAILED DESCRIPTION

Aspects of the present disclosure provide a memory device that provides both high bandwidth and high capacity and a method performed thereby.

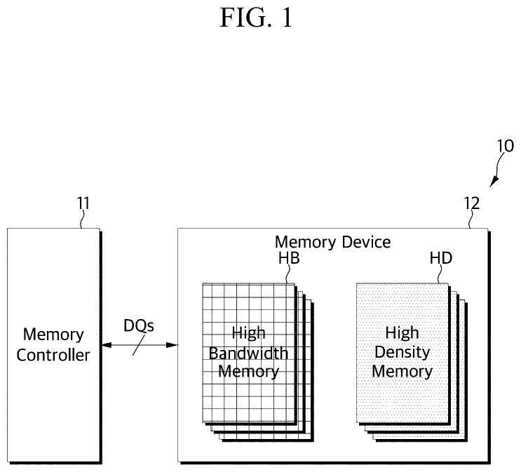

FIG. 1 is a block diagram illustrating a storage device 10 according to example embodiments of the present disclosure. The storage device 10 may store data or provide stored data to a host in response to a request from the host. The storage device 10 may be referred to as a storage system or a memory system. As illustrated in FIG. 1, the storage device 10 includes a memory controller 11 and a memory device 12. In some example embodiments, the memory controller 11 and the memory device 12 may be manufactured by a semiconductor process and may be included in a single package or in separate packages.

The memory controller 11 may communicate with the host and the memory device 12 and may control data exchange between the host and the memory device 12. For example, the memory controller 11 may write data to the memory device 12 or read stored data from the memory device 12 in response to a request received from the host. The memory controller 11 may communicate with the memory device 12 through a plurality of channels. For example, as illustrated in FIG. 1, the memory controller 11 may transmit or receive data sets DQs to the memory device 12 or from the memory device 12 through the plurality of channels. As used herein, a data set may refer to a unit of data transferred through a single channel including a plurality of lines and may be a multi-bit value. As the number of channels increases, the amount of data transferred in parallel may increase, thereby providing higher bandwidth.

The memory device 12 may include a high-bandwidth memory HB and a high-density memory HD. The high-bandwidth memory HB may have a wide input/output (IO). For example, the high-bandwidth memory HB may include at least one memory chip (or memory die) that includes a relatively large number of data pad sets, thereby enabling high-speed data writing or reading. As used herein, a data pad set may refer to a unit of pads exposed externally from a chip for outputting or receiving a single data set. The high-density memory HD may include at least one memory chip (or memory die) that includes a relatively small number of data pad sets while having a high integration density of memory cells (or bits), thereby storing a large amount of data.

As will be described below with reference to the drawings, the memory device 12 may provide high bandwidth and high capacity. As a result, performance and efficiency of the storage device 10 and a system including the storage device 10 may be enhanced. Data may be transferred between the high-bandwidth memory HB and the high-density memory HD within the memory device 12, enabling access to a large amount of data at high bandwidth.

In some example embodiments, the high-bandwidth memory HB and the high-density memory HD may include volatile memory cells. For example, the high-bandwidth memory HB and the high-density memory HD may be dynamic random access memories (DRAMs) such as double data rate (DDR) synchronous dynamic random access memory (SDRAM), DDR2 SDRAM, DDR3 SDRAM, DDR4 SDRAM, DDR5 SDRAM, DDR6 SDRAM, low power double data rate (LPDDR) SDRAM, LPDDR2 SDRAM, LPDDR3 SDRAM, LPDDR4 SDRAM, LPDDR4X SDRAM, LPDDR5 SDRAM, graphics double data rate (GDDR) synchronous graphics random access memory (SGRAM), GDDR2 SGRAM, GDDR3 SGRAM, GDDR4 SGRAM, GDDR5 SGRAM, and GDDR6 SGRAM. In some example embodiments, the high-bandwidth memory HB and the high-density memory HD may include a vertical channel transistor (VCT). In some example embodiments, the high-bandwidth memory HB and the high-density memory HD may be nonvolatile memory devices including nonvolatile memory cells. For example, the high-bandwidth memory HB and the high-density memory HD may be nonvolatile memory devices such as NAND flash memory, NOR flash memory, and resistive random access memory (RRAM). Although flash memory is mainly described below as a nonvolatile memory, it is noted that example embodiments of the present disclosure are not limited thereto.

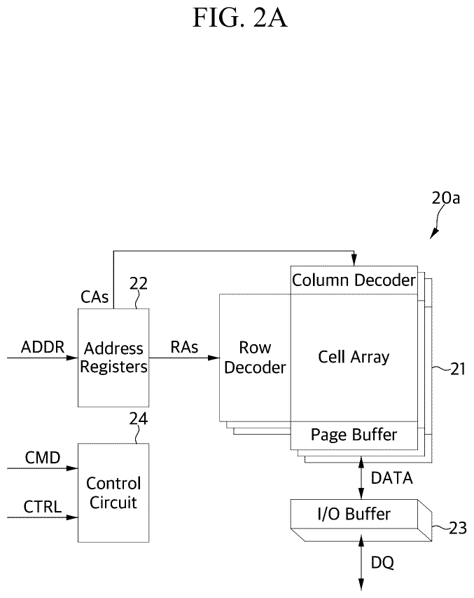

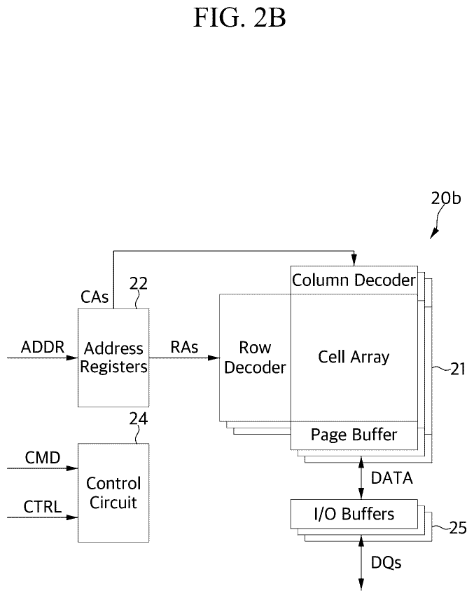

FIGS. 2A and 2B are block diagrams illustrating examples of memory according to example embodiments of the present disclosure. For example, FIG. 2A illustrates a high-density memory 20a and FIG. 2B illustrates a high-bandwidth memory 20b. Hereinafter, redundant descriptions between FIGS. 2A and 2B will be omitted.

Referring to FIG. 2A, the high-density memory 20a may include planes 21, address registers 22, an input/output (I/O) buffer 23, and a control circuit 24. The planes 21 may receive row addresses RAs and column addresses CAs from the address registers 22 and may exchange data DATA with the input/output buffer 23. In some example embodiments, the high-density memory 20a may include an error correction code (ECC) engine between the planes 21 and the input/output buffer 23, and the planes 21 may exchange a codeword with the ECC engine. In some example embodiments, the high-density memory 20a may include a single plane. As illustrated in FIG. 2A, each of the planes 21 may include a cell array, a row decoder, a column decoder and a page buffer.

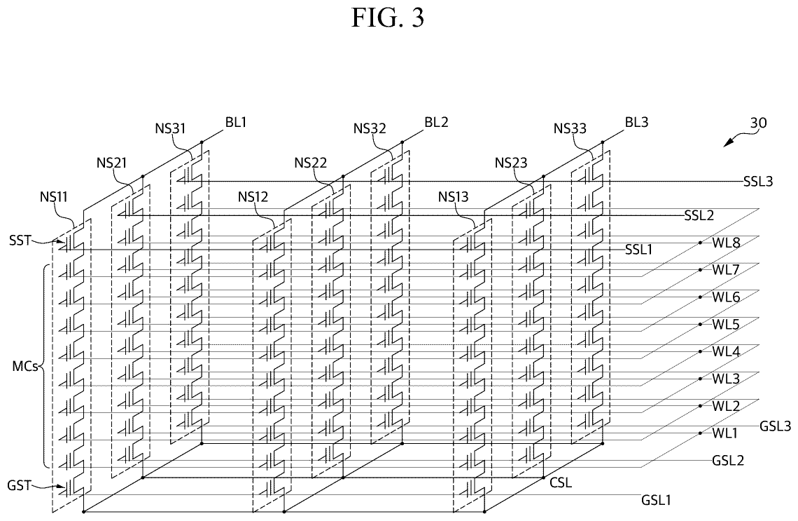

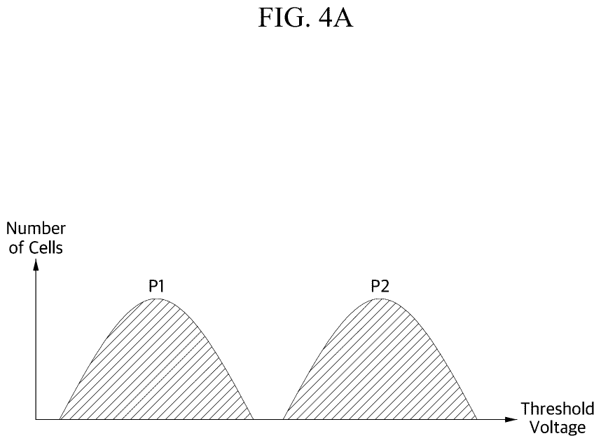

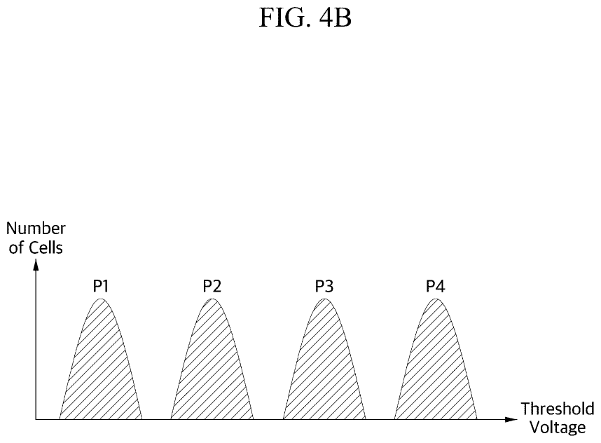

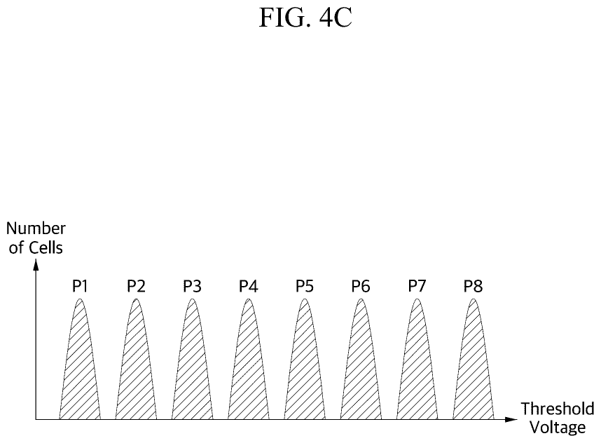

The cell array may include a plurality of memory cells. For example, in flash memory, a memory cell may include a transistor having a floating gate and may store data corresponding to a threshold voltage of the transistor. As will be described below with reference to FIGS. 4A, 4B, and 4C, a memory cell may store one or more bits. When each memory cell stores a single bit, memory cells connected to the same word line may store one page, whereas when each memory cell stores two or more bits, memory cells connected to the same word line may store two or more pages. The page buffer may store a page to be programmed into the cell array or a page read from the cell array. The cell array may include a plurality of blocks, and a block may include memory cells connected to a plurality of word lines. Reading and writing may be performed in page units, whereas erasing may be performed in block units. An example of a block will be described below with reference to FIG. 3.

The row decoder may be connected to the cell array through word lines. The row decoder may activate one of the word lines according to one of the row addresses RAs, and memory cells connected to the activated word line in the cell array may be selected. The column decoder may select a portion of the memory cells selected by the row addresses RAs according to one of the column addresses CAs. For example, the column decoder may select the data DATA as a portion of a page. The page buffer may store data to be programmed into the cell array or data read from the cell array. The page buffer may exchange the data DATA with the input/output buffer 23 as a portion of a page.

The address registers 22 may receive an address ADDR provided from outside the high-density memory 20a, for example, from the memory controller 11 of FIG. 1, and may store the address ADDR. In some example embodiments, the address registers 22 may extract the row addresses RAs and the column addresses CAs from the address ADDR. As illustrated in FIG. 2A, the address registers 22 may provide the row addresses RAs and the column addresses CAs to the planes 21.

The input/output buffer 23 may exchange the data DATA with the planes 21, that is, with page buffers. For example, the input/output buffer 23 may provide the data DATA from a data set DQ received by the high-density memory 20a to the page buffers and may output the data set DQ to the outside of the high-density memory 20a from the data DATA received from the page buffers.

The control circuit 24 may receive a command CMD and a control signal CTRL received by the high-density memory 20a. The control circuit 24 may decode the command CMD and may generate control signals to control components of the high-density memory 20a based on the decoded command CMD. For example, the control circuit 24 may receive a read command, a write command, or an erase command and may generate control signals to perform a read operation, a write operation, or an erase operation.

Referring to FIG. 2B, the high-bandwidth memory 20b may include the planes 21, the address registers 22, the control circuit 24, and input/output (I/O) buffers 25. Compared to the high-density memory 20a of FIG. 2A, the high-bandwidth memory 20b may include the input/output buffers 25 that transmit and receive the data sets DQs. The input/output buffers 25 may output the data sets DQs to the outside of the high-bandwidth memory 20b from the data DATA received from the planes 21, that is, from the page buffers. Further, the input/output buffers 25 may provide the data DATA from the data sets DQs received by the high-bandwidth memory 20b to the page buffers. The input/output buffers 25 may correspond to the planes 21, respectively, and the data sets DQs may also correspond to the planes 21, respectively. As described above with reference to FIG. 1, the high-bandwidth memory 20b may include a relatively large number of data pad sets for the data sets DQs. Due to the data sets DQs transmitted and received in parallel, the high-bandwidth memory 20b may provide high bandwidth.

FIG. 3 is a circuit diagram illustrating a memory block 30 according to example embodiments of the present disclosure. For example, the memory block 30 may correspond to one of a plurality of blocks included in the cell array of FIGS. 2A and 2B. As illustrated in FIG. 3, the memory block 30 may include a plurality of NAND strings NS11, NS12, NS13, NS21, NS22, NS23, NS31, NS32, and NS33.

Each of the NAND strings may include a string select transistor SST, memory cells MCs, and a ground select transistor GST connected in series. The string select transistor SST, the memory cells MCs, and the ground select transistor GST may form a structure stacked along a vertical direction on a substrate. The string select transistor SST may be connected to one of string select lines SSL1, SSL2, and SSL3. The string select transistor SST may also be connected to one of bit lines BL1, BL2, and BL3. The memory cells MCs may be connected to word lines WL1, WL2, WL3, WL4, WL5, WL6, WL7, and WL8, respectively. The ground select transistor GST may be connected to one of ground select lines GSL1, GSL2, and GSL3. The ground select transistor GST may also be connected to a common source line CSL. The number of NAND strings, the number of word lines, the number of bit lines, the number of ground select lines, and the number of string select lines are not limited to those illustrated in FIG. 3.

FIGS. 4A, 4B, and 4C are diagrams illustrating distributions of memory cells according to example embodiments of the present disclosure. For example, FIG. 4A illustrates a distribution of memory cells storing 1 bit, FIG. 4B illustrates a distribution of memory cells storing 2 bits, and FIG. 4C illustrates a distribution of memory cells storing 3 bits. A memory cell may have a threshold voltage corresponding to the stored bits, and FIGS. 4A, 4B, and 4C illustrate distributions of memory cells according to threshold voltage. Hereinafter, FIGS. 4A, 4B, and 4C will be described with reference to FIGS. 2A and 2B.

Referring to FIG. 4A, a memory cell storing 1 bit may be referred to as a single level cell (SLC) and may have a first state P1 or a second state P2. Referring to FIG. 4B, a memory cell storing 2 bits may be referred to as a multi-level cell (MLC) and may have one of the first state P1, the second state P2, a third state P3, and a fourth state P4. Referring to FIG. 4C, a memory cell storing 3 bits may be referred to as a triple-level cell (TLC) and may have one of the first state P1, the second state P2, the third state P3, the fourth state P4, a fifth state P5, a sixth state P6, a seventh state P7, and an eighth state P8.

In some example embodiments, the cell array of the high-bandwidth memory 20b may include a first memory cell configured to store at least one bit, and the cell array of the high-density memory 20a may include a second memory cell configured to store more bits than the bit of the first memory cell. For example, the cell array of the high-bandwidth memory 20b may include an SLC, while the cell array of the high-density memory 20a may include an MLC or a TLC. As a result, the high-density memory 20a may have high capacity, while the high-bandwidth memory 20b may have high access speed.

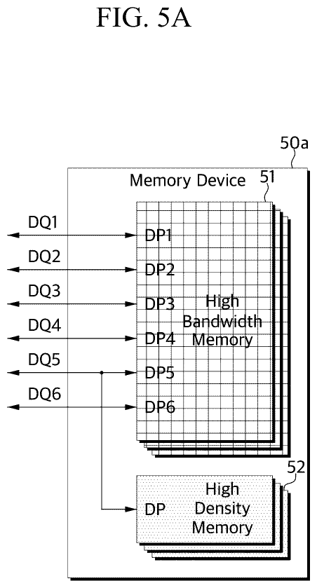

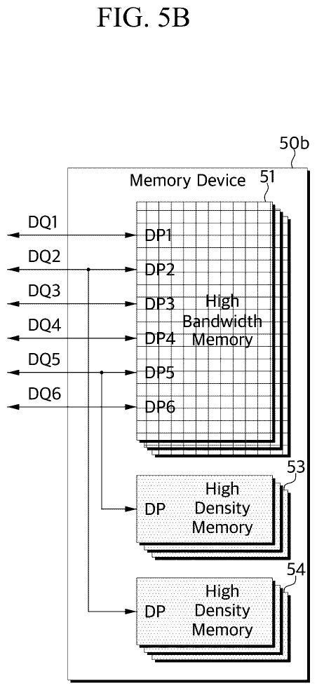

FIGS. 5A and 5B are block diagrams illustrating examples of a memory device according to example embodiments of the present disclosure. For example, FIGS. 5A and 5B illustrate memory devices 50a and 50b including a high-bandwidth memory and a high-density memory that share at least one data set. FIGS. 5A and 5B illustrate the memory devices 50a and 50b that receive or output a first data set DQ1, a second data set DQ2, a third data set DQ3, a fourth data set DQ4, a fifth data set DQ5, and a sixth data set DQ6 in parallel, but example embodiments of the present disclosure are not limited thereto. For example, a memory device may receive or output a plurality of data sets less than six or more than six in parallel. Hereinafter, descriptions of FIGS. 5A and 5B that overlap with the above descriptions will be omitted.

Referring to FIG. 5A, the memory device 50a may include a high-bandwidth memory 51 and a high-density memory 52. The high-bandwidth memory 51 may include a first data pad set DP1, a second data pad set DP2, a third data pad set DP3, a fourth data pad set DP4, a fifth data pad set DP5, and a sixth data pad set DP6. The first to sixth data pad sets DP1 to DP6 may receive or output the first to sixth data sets DQ1 to DQ6, respectively.

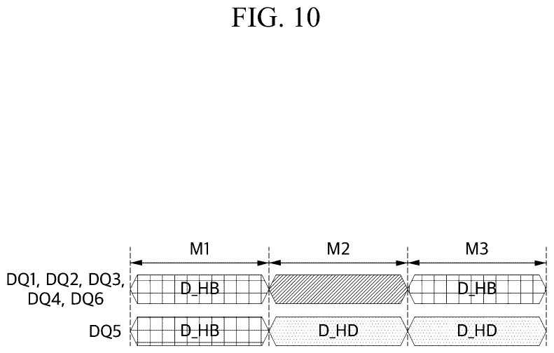

The high-density memory 52 may include a data pad set DP. The data pad set DP of the high-density memory 52 may be connected to one of the first to sixth data pad sets DP1 to DP6 of the high-bandwidth memory 51. For example, as illustrated in FIG. 5A, the data pad set DP of the high-density memory 52 may be connected to the fifth data pad set DP5 of the high-bandwidth memory 51. As a result, as will be described below with reference to FIG. 10, the fifth data set DQ5 may be output from the high-bandwidth memory 51 or the high-density memory 52 or provided to the high-bandwidth memory 51 or the high-density memory 52 depending on a mode.

Referring to FIG. 5B, the memory device 50b may include the high-bandwidth memory 51, a first high-density memory 53, and a second high-density memory 54. The high-bandwidth memory 51 may include the first to sixth data pad sets DP1 to DP6. The first to sixth data pad sets DP1 to DP6 may receive or output the first to sixth data sets DQ1 to DQ6, respectively.

Each of the first high-density memory 53 and the second high-density memory 54 may include the data pad set DP. The data pad set DP of each of the first high-density memory 53 and the second high-density memory 54 may be connected to one of the first to sixth data pad sets DP1 to DP6 of the high-bandwidth memory 51. For example, as illustrated in FIG. 5B, the data pad set DP of the first high-density memory 53 may be connected to the fifth data pad set DP5 of the high-bandwidth memory 51. The data pad set DP of the second high-density memory 54 may also be connected to the second data pad set DP2 of the high-bandwidth memory 51. As a result, the fifth data set DQ5 may be output from the high-bandwidth memory 51 or the first high-density memory 53 or provided to the high-bandwidth memory 51 or the first high-density memory 53 depending on a mode. Also, the second data set DQ2 may be output from the high-bandwidth memory 51 or the second high-density memory 54 or provided to the high-bandwidth memory 51 or the second high-density memory 54 depending on a mode.

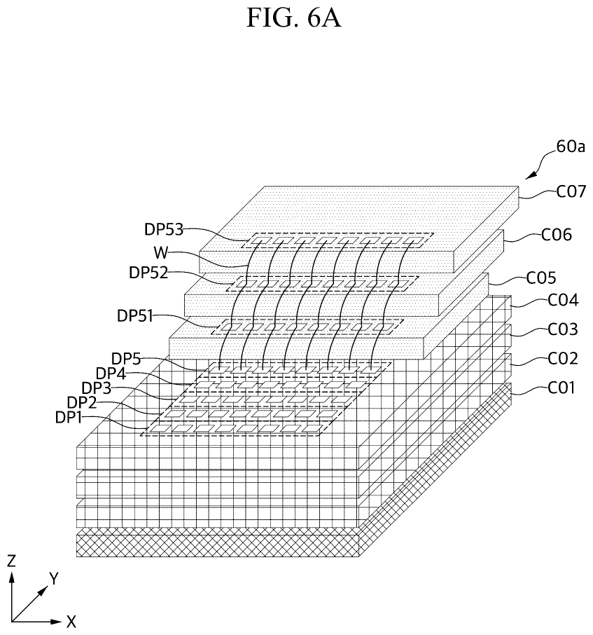

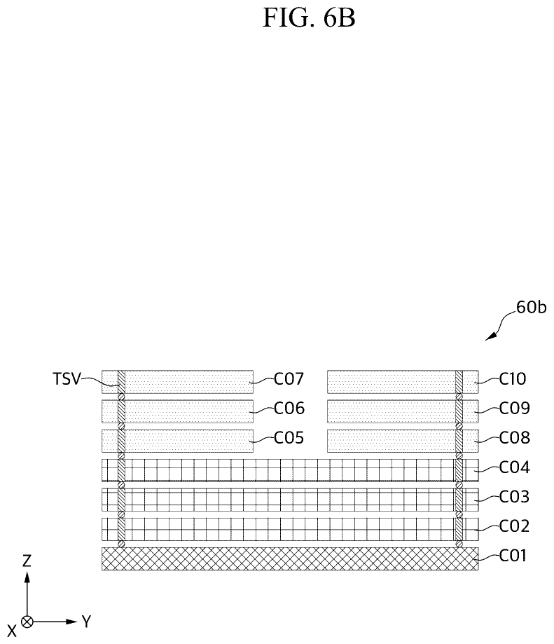

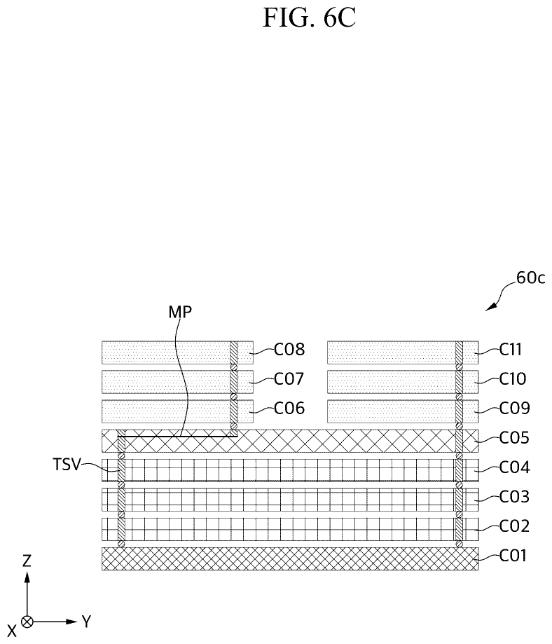

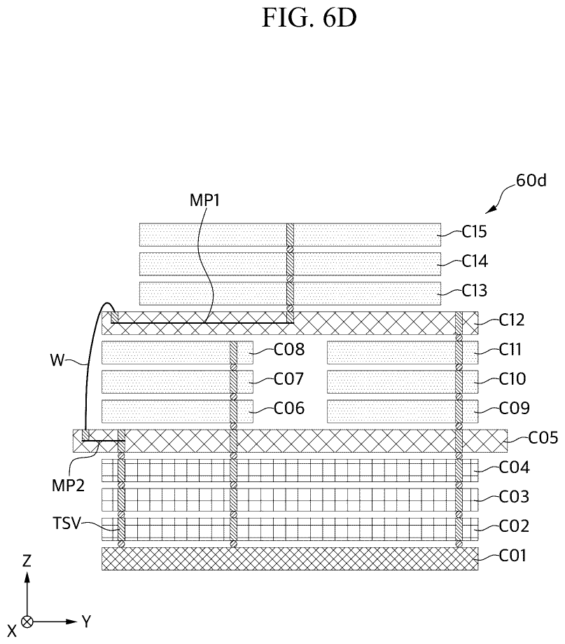

FIGS. 6A, 6B, 6C, and 6D are diagrams illustrating examples of a device according to example embodiments of the present disclosure. For example, FIGS. 6A, 6B, 6C, and 6D illustrate devices 60a, 60b, 60c, and 60d including a high-bandwidth memory and a high-density memory that share at least one data set, as described above with reference to FIGS. 5A and 5B. In some example embodiments, the high-bandwidth memory and/or the high-density memory may include a number of chips different from those illustrated in FIGS. 6A, 6B, 6C, and 6D. Hereinafter, redundant descriptions among FIGS. 6A, 6B, 6C, and 6D will be omitted.

Referring to FIG. 6A, the device 60a may include a first chip C01, a second chip C02, a third chip C03, a fourth chip C04, a fifth chip C05, a sixth chip C06, and a seventh chip C07 stacked in a Z-axis direction. The first chip C01 may be a base chip or a base die, and the second to seventh chips C02 to C07 may be memory chips. As used herein, an X-axis direction and a Y-axis direction may be referred to as a first direction and a second direction, respectively, and the Z-axis direction may be referred to as a vertical direction or a third direction. A plane formed by the X-axis and the Y-axis may be referred to as a horizontal plane. A component disposed relatively in the +Z direction with respect to another component may be referred to as being above the other component, and a component disposed relatively in the −Z direction with respect to another component may be referred to as being below the other component. An area of a component may refer to a size occupied by the component in a plane parallel to the horizontal plane, and a width of a component may refer to a length in a direction orthogonal to a direction in which the component extends. A surface exposed in the +Z direction may be referred to as a top surface, a surface exposed in the −Z direction may be referred to as a bottom surface, and a surface exposed in the ±X direction or the ±Y direction may be referred to as a side surface.

The first chip C01 may be electrically connected to the memory chips and may communicate with the memory chips. In some example embodiments, the device 60a may correspond to the memory device 12 of FIG. 1. For example, the first chip C01 may include a logic circuit and may provide an interface between the outside of the device 60a, for example, the memory controller 11 of FIG. 1, and the memory chips. In some example embodiments, the device 60a may correspond to the storage device 10 of FIG. 1, and the first chip C01 may include the memory controller 11 of FIG. 1.

The second to fourth chips C02 to C04 may be disposed above the first chip C01 and may correspond to the high-bandwidth memory. The fifth to seventh chips C05 to C07 may be disposed above the second to fourth chips C02 to C04 and may correspond to the high-density memory. As described above with reference to the drawings, the high-bandwidth memory may include a plurality of data pad sets. For example, as illustrated in FIG. 6A, the fourth chip C04 as the high-bandwidth memory may include the first to fifth data pad sets DP1 to DP5. Although not illustrated in FIG. 6A, the fourth chip C04 may further include the sixth data pad set DP6. The first to sixth data pad sets DP1 to DP6 of the fourth chip C04 may be electrically connected to the first to sixth data pad sets DP1 to DP6 of each of the first to third chips C01 to C03 through through silicon vias, for example.

In some example embodiments, a data pad set of the high-bandwidth memory and a data pad set of the high-density memory may be electrically connected to each other through wires. For example, as in the memory device 50a of FIG. 5A, the high-bandwidth memory and the high-density memory may share the fifth data set DQ5. To this end, the data pad set of the high-density memory may be electrically connected to the fifth data pad set DP5 of the high-bandwidth memory. For example, as illustrated in FIG. 6A, the fifth to seventh chips C05 to C07 may include data pad sets DP51, DP52, and DP53, respectively, and the data pad sets DP51 to DP53 may be electrically connected to the fifth data pad set DP5 of the fourth chip C04 through a wire W.

Referring to FIG. 6B, the device 60b may include the first chip C01, the second chip C02, the third chip C03, the fourth chip C04, the fifth chip C05, the sixth chip C06, the seventh chip C07, an eighth chip C08, a ninth chip C09, and a tenth chip C10 stacked in the Z-axis direction. The first chip C01 may be a base chip or a base die, and the second to tenth chips C02 to C10 may be memory chips. The first chip C01 may be electrically connected to the memory chips and may communicate with the memory chips. In some example embodiments, the device 60b may correspond to the memory device 12 of FIG. 1. For example, the first chip C01 may include a logic circuit and may provide an interface between the outside of the device 60b, for example, the memory controller 11 of FIG. 1, and the memory chips. In some example embodiments, the device 60b may correspond to the storage device 10 of FIG. 1, and the first chip C01 may include the memory controller 11 of FIG. 1. The second to fourth chips C02 to C04 may be disposed above the first chip C01 and may correspond to the high-bandwidth memory. The fifth to tenth chips C05 to C10 may be disposed above the second to fourth chips C02 to C04 and may correspond to the high-density memory.

In some example embodiments, a data pad set of the high-bandwidth memory and a data pad set of the high-density memory may be electrically connected to each other through through silicon vias. For example, as in the memory device 50b of FIG. 5B, the high-bandwidth memory and the high-density memory may share two or more data sets. To this end, data pad sets of the high-density memory may be electrically connected to data pad sets of the high-bandwidth memory. For example, the fifth to seventh chips C05 to C07 may correspond to the first high-density memory 53 of FIG. 5B, and a data pad set of each of the fifth to seventh chips C05 to C07 may be electrically connected to data pad sets of the first to fourth chips C01 to C04 through a through silicon via TSV. Also, the eighth to tenth chips C08 to C10 may correspond to the second high-density memory 54 of FIG. 5B, and a data pad set of each of the eighth to tenth chips C08 to C10 may be electrically connected to the data pad sets of the first to fourth chips C01 to C04 through the through silicon via TSV.

Referring to FIG. 6C, the device 60c may include the first chip C01, the second chip C02, the third chip C03, the fourth chip C04, the fifth chip C05, the sixth chip C06, the seventh chip C07, the eighth chip C08, the ninth chip C09, the tenth chip C10, and an eleventh chip C11 stacked in the Z-axis direction. The first chip C01 may be a base chip or a base die, the second to fourth chips C02 to C04 and the sixth to eleventh chips C06 to C11 may be memory chips, and the fifth chip C05 may be a redistribution chip. The first chip C01 may be electrically connected to the memory chips and may communicate with the memory chips. In some example embodiments, the device 60c may correspond to the memory device 12 of FIG. 1. For example, the first chip C01 may include a logic circuit and may provide an interface between the outside of the device 60c, for example, the memory controller 11 of FIG. 1, and the memory chips. In some example embodiments, the device 60c may correspond to the storage device 10 of FIG. 1, and the first chip C01 may include the memory controller 11 of FIG. 1. The second to fourth chips C02 to C04 may be disposed above the first chip C01 and may correspond to the high-bandwidth memory. The sixth to eleventh chips C06 to C11 may be disposed above the fifth chip C05 and may correspond to the high-density memory.

In some example embodiments, a redistribution chip may be disposed between the high-bandwidth memory and the high-density memory. For example, as illustrated in FIG. 6C, the fifth chip C05 as the redistribution chip may be disposed above the fourth chip C04, and the sixth to eleventh chips C06 to C11 may be disposed above the fifth chip C05. The fifth chip C05 may include patterns that connect a data pad set of the high-bandwidth memory and a data pad set of the high-density memory. As illustrated in FIG. 6C, the fifth chip C05 may include a pattern MP, and the pattern MP may be included in a path between a data pad of the fourth chip C04 and a data pad of the sixth chip C06. In some example embodiments, the pattern MP may be disposed in a wiring layer (for example, a metal layer) of the fifth chip C05.

Referring to FIG. 6D, the device 60d may include the first chip C01, the second chip C02, the third chip C03, the fourth chip C04, the fifth chip C05, the sixth chip C06, the seventh chip C07, the eighth chip C08, the ninth chip C09, the tenth chip C10, the eleventh chip C11, a twelfth chip C12, a thirteenth chip C13, a fourteenth chip C14, and a fifteenth chip C15 stacked in the Z-axis direction. The first chip C01 may be a base chip or a base die, the second to fourth chips C02 to C04, the sixth to eleventh chips C06 to C11, and the thirteenth to fifteenth chips C13 to C15 may be memory chips, and the fifth chip C05 and the twelfth chip C12 may be redistribution chips. The first chip C01 may be electrically connected to the memory chips and may communicate with the memory chips. In some example embodiments, the device 60d may correspond to the memory device 12 of FIG. 1. For example, the first chip C01 may include a logic circuit and may provide an interface between the outside of the device 60d, for example, the memory controller 11 of FIG. 1, and the memory chips. In some example embodiments, the device 60d may correspond to the storage device 10 of FIG. 1, and the first chip C01 may include the memory controller 11 of FIG. 1. The second to fourth chips C02 to C04 may be disposed above the first chip C01 and may correspond to the high-bandwidth memory. The sixth to eleventh chips C06 to C11 and the thirteenth to fifteenth chips C13 to C15 may correspond to the high-density memory.

In some example embodiments, a redistribution chip may be disposed between high-density memories. For example, as illustrated in FIG. 6D, the twelfth chip C12 as the redistribution chip may be disposed above the eighth chip C08 and the eleventh chip C11, and the thirteenth to fifteenth chips C13 to C15 may be disposed above the twelfth chip C12. The twelfth chip C12 may include patterns included in a path between a data pad set of the high-bandwidth memory and a data pad set of the high-density memory. As illustrated in FIG. 6D, the twelfth chip C12 may include a first pattern MP1, and the first pattern MP1 may be included in a path between a data pad of the fourth chip C04 and a data pad of the thirteenth chip C13. As illustrated in FIG. 6D, the wire W may connect a pad of the twelfth chip C12 and a pad of the fifth chip C05, and the fifth chip C05 may include a second pattern MP2 between the wire W and a pad of the fourth chip C04. In some example embodiments, the first pattern MP1 may be disposed in a wiring layer (for example, a metal layer) of the twelfth chip C12, and the second pattern MP2 may be disposed in a wiring layer (for example, a metal layer) of the fifth chip C05.

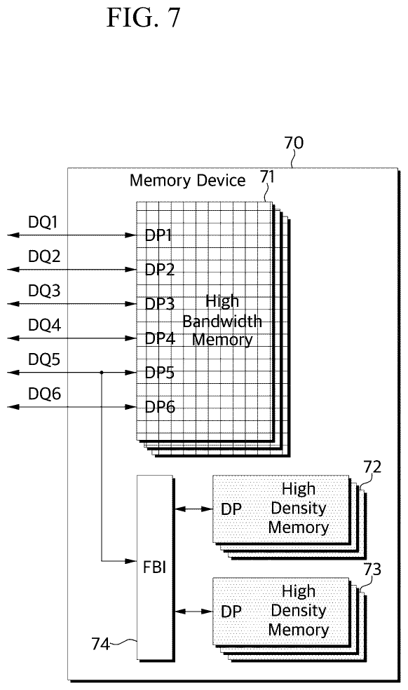

FIG. 7 is a block diagram illustrating a memory device 70 according to example embodiments of the present disclosure. For example, FIG. 7 illustrates the memory device 70 including a high-bandwidth memory and a high-density memory that share at least one data set. FIG. 7 illustrates the memory device 70 that receives or outputs the first to sixth data sets DQ1 to DQ6 in parallel, but example embodiments of the present disclosure are not limited thereto. For example, a memory device may receive or output a plurality of data sets less than six or more than six in parallel. Hereinafter, descriptions of FIG. 7 that overlap with the above descriptions will be omitted.

Referring to FIG. 7, the memory device 70 may include a high-bandwidth memory 71, a first high-density memory 72, a second high-density memory 73, and a frequency boosting interface (FBI) 74. The high-bandwidth memory 71 may include the first to sixth data pad sets DP1 to DP6. The first to sixth data pad sets DP1 to DP6 may receive or output the first to sixth data sets DQ1 to DQ6, respectively. Each of the first high-density memory 72 and the second high-density memory 73 may include the data pad set DP.

The FBI 74 may connect one of the data pad set DP of the first high-density memory 72 and the data pad set DP of the second high-density memory 73 to the fifth data pad set DP5 of the high-bandwidth memory 71 depending on a connection mode. For example, as illustrated in FIG. 7, the FBI 74 may be connected to the data pad set DP of the first high-density memory 72 and the data pad set DP of the second high-density memory 73 and may be connected to the fifth data pad set DP5 of the high-bandwidth memory 71. To this end, the FBI 74 may include a switch set including a plurality of switches. The switch set may electrically connect the data pad set DP of the first high-density memory 72 to the fifth data pad set DP5 in a first connection mode and may electrically connect the data pad set DP of the second high-density memory 73 to the fifth data pad set DP5 in a second connection mode. As a result, a load on the fifth data set DQ5 may be reduced, and a frequency of the fifth data set DQ5 may increase. In some example embodiments, the FBI 74 may be implemented as a single chip and may be disposed between the high-bandwidth memory 71 and the first high-density memory 72 (and/or the second high-density memory 73).

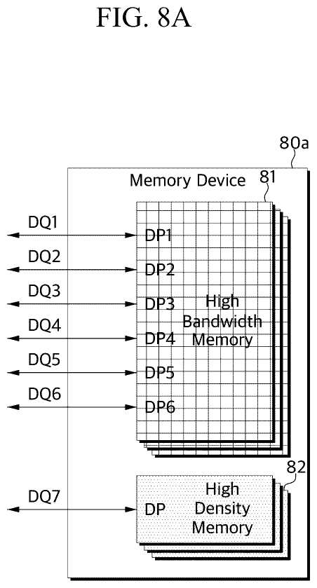

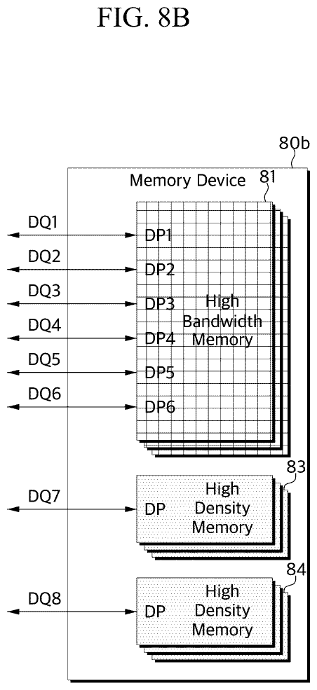

FIGS. 8A and 8B are block diagrams illustrating examples of a memory device according to example embodiments of the present disclosure. For example, FIGS. 8A and 8B illustrate memory devices 80a and 80b including a high-bandwidth memory and a high-density memory that do not share a data set. A memory device is not limited to the number of data sets illustrated in FIGS. 8A and 8B. Hereinafter, descriptions of FIGS. 8A and 8B that overlap with the above descriptions will be omitted.

Referring to FIG. 8A, the memory device 80a may include a high-bandwidth memory 81 and a high-density memory 82 and may receive or output the first data set DQ1, the second data set DQ2, the third data set DQ3, the fourth data set DQ4, the fifth data set DQ5, the sixth data set DQ6, and a seventh data set DQ7. The high-bandwidth memory 81 may include the first to sixth data pad sets DP1 to DP6. The first to sixth data pad sets DP1 to DP6 may receive or output the first to sixth data sets DQ1 to DQ6, respectively. The high-density memory 82 may include the data pad set DP, and the data pad set DP may receive or output the seventh data set DQ7. As a result, the high-bandwidth memory 81 and the high-density memory 82 may receive or output data sets independently of each other.

Referring to FIG. 8B, the memory device 80b may include the high-bandwidth memory 81, a first high-density memory 83, and a second high-density memory 84 and may receive or output the first data set DQ1, the second data set DQ2, the third data set DQ3, the fourth data set DQ4, the fifth data set DQ5, the sixth data set DQ6, the seventh data set DQ7, and an eighth data set DQ8. The high-bandwidth memory 81 may include the first to sixth data pad sets DP1 to DP6. The first to sixth data pad sets DP1 to DP6 may receive or output the first to sixth data sets DQ1 to DQ6, respectively. The first high-density memory 83 may include the data pad set DP, and the data pad set DP may receive or output the seventh data set DQ7. The second high-density memory 84 may include the data pad set DP, and the data pad set DP may receive or output the eighth data set DQ8. As a result, the high-bandwidth memory 81, the first high-density memory 83, and the second high-density memory 84 may receive or output data sets independently of each other.

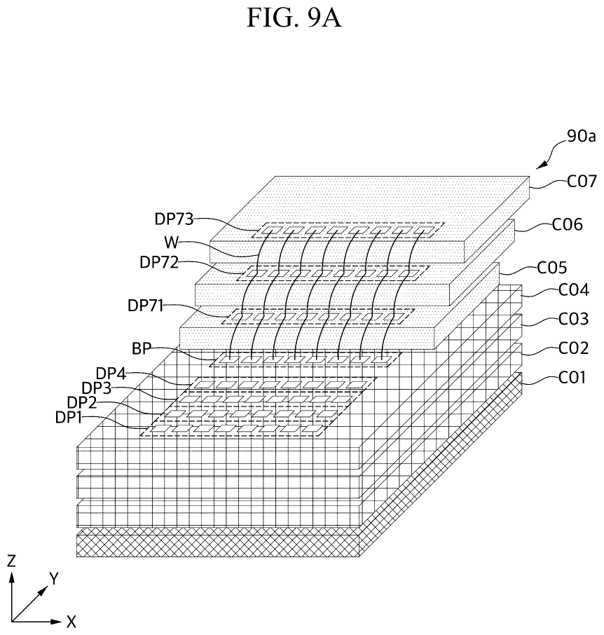

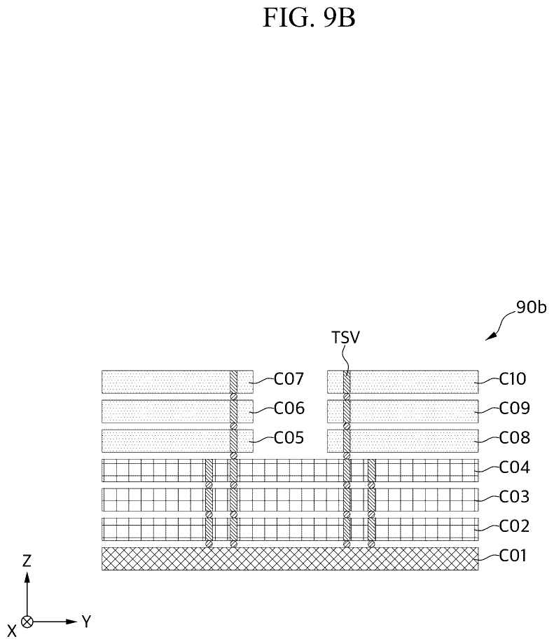

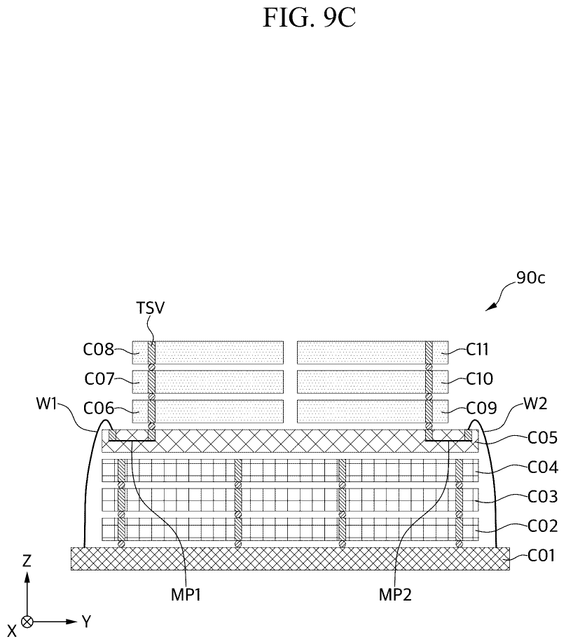

FIGS. 9A, 9B, and 9C are diagrams illustrating examples of a device according to example embodiments of the present disclosure. For example, FIGS. 9A, 9B, and 9C illustrate devices 90a, 90b, and 90c including a high-bandwidth memory and a high-density memory that do not share a data set, as described above with reference to FIGS. 8A and 8B. In some example embodiments, the high-bandwidth memory and/or the high-density memory may include a number of chips different from those illustrated in FIGS. 9A, 9B, and 9C. Hereinafter, descriptions of FIGS. 9A, 9B, and 9C that overlap with the above descriptions will be omitted.

Referring to FIG. 9A, the device 90a may include the first to seventh chips C01 to C07 stacked in the Z-axis direction. The first chip C01 may be a base chip or a base die, and the second to seventh chips C02 to C07 may be memory chips. The first chip C01 may be electrically connected to the memory chips and may communicate with the memory chips. In some example embodiments, the device 90a may correspond to the memory device 12 of FIG. 1. For example, the first chip C01 may include a logic circuit and may provide an interface between the outside of the device 90a, for example, the memory controller 11 of FIG. 1, and the memory chips. In some example embodiments, the device 90a may correspond to the storage device 10 of FIG. 1, and the first chip C01 may include the memory controller 11 of FIG. 1.

The second to fourth chips C02 to C04 may be disposed above the first chip C01 and may correspond to the high-bandwidth memory. The fifth to seventh chips C05 to C07 may be disposed above the second to fourth chips C02 to C04 and may correspond to the high-density memory. The fourth chip C04 as the high-bandwidth memory may include the first to fourth data pad sets DP1 to DP4. Although not illustrated in FIG. 9A, the fourth chip C04 may further include the fifth data pad set DP5 and the sixth data pad set DP6. The first to sixth data pad sets DP1 to DP6 of the fourth chip C04 may be electrically connected to the first to sixth data pad sets DP1 to DP6 of each of the first to third chips C01 to C03 through through silicon vias, for example.

In some example embodiments, a data pad set of the high-density memory may be connected to a bypass pad set of the high-bandwidth memory through the wire W. As used herein, a bypass pad set may refer to a pad set insulated from an internal circuit of a chip and included in a path passing through the chip. For example, as illustrated in FIG. 9A, the fifth to seventh chips C05 to C07 may include data pad sets DP71, DP72, and DP73, respectively. Also, the data pad sets DP71 to DP73 may be connected to a bypass pad set BP of the fourth chip C04 through the wire W. The bypass pad set BP may be insulated from a circuit of the fourth chip C04 and may be electrically connected to a bypass pad set of each of the first to third chips C01 to C03 through through silicon vias. As a result, the data pad sets DP71 to DP73 of the fifth to seventh chips C05 to C07 may be electrically connected to the first chip C01 independently from circuits of the second to fourth chips C02 to C04.

Referring to FIG. 9B, the device 90b may include the first to tenth chips C01 to C10 stacked in the Z-axis direction. The first chip C01 may be a base chip or a base die, and the second to tenth chips C02 to C10 may be memory chips. The first chip C01 may be electrically connected to the memory chips and may communicate with the memory chips. In some example embodiments, the device 90b may correspond to the memory device 12 of FIG. 1. For example, the first chip C01 may include a logic circuit and may provide an interface between the outside of the device 90b, for example, the memory controller 11 of FIG. 1, and the memory chips. In some example embodiments, the device 90b may correspond to the storage device 10 of FIG. 1, and the first chip C01 may include the memory controller 11 of FIG. 1. The second to fourth chips C02 to C04 may be disposed above the first chip C01 and may correspond to the high-bandwidth memory. The fifth to tenth chips C05 to C10 may be disposed above the second to fourth chips C02 to C04 and may correspond to the high-density memory.

In some example embodiments, a data pad set of the high-density memory may be electrically connected to a bypass pad set of the high-bandwidth memory through through silicon vias. For example, as illustrated in FIG. 9B, the fifth to seventh chips C05 to C07 may be connected to a bypass pad set of the fourth chip C04 through through silicon vias and may be electrically connected to the first chip C01 through through silicon vias of the first to fourth chips C01 to C04. Also, the eighth to tenth chips C08 to C10 may be connected to the bypass pad set of the fourth chip C04 through through silicon vias and may be electrically connected to the first chip C01 through the through silicon vias of the first to fourth chips C01 to C04.

Referring to FIG. 9C, the device 90c may include the first to eleventh chips C01 to C11 stacked in the Z-axis direction. The first chip C01 may be a base chip or a base die, the second to fourth chips C02 to C04 and the sixth to eleventh chips C06 to C11 may be memory chips, and the fifth chip C05 may be a redistribution chip. The first chip C01 may be electrically connected to the memory chips and may communicate with the memory chips. In some example embodiments, the device 90c may correspond to the memory device 12 of FIG. 1. For example, the first chip C01 may include a logic circuit and may provide an interface between the outside of the device 90c, for example, the memory controller 11 of FIG. 1, and the memory chips. In some example embodiments, the device 90c may correspond to the storage device 10 of FIG. 1, and the first chip C01 may include the memory controller 11 of FIG. 1. The second to fourth chips C02 to C04 may be disposed above the first chip C01 and may correspond to the high-bandwidth memory. The sixth to eleventh chips C06 to C11 may be disposed above the fifth chip C05 and may correspond to the high-density memory.

In some example embodiments, a redistribution chip may be disposed between the high-bandwidth memory and the high-density memory. For example, as illustrated in FIG. 9C, the fifth chip C05 as the redistribution chip may be disposed above the fourth chip C04, and the sixth to eleventh chips C06 to C11 may be disposed above the fifth chip C05. The fifth chip C05 may include patterns for connecting a data pad set of the high-density memory and a data pad set of the first chip C01. For example, as illustrated in FIG. 9C, the fifth chip C05 may include the first pattern MP1, and the first pattern MP1 and a first wire W1 may be included in a path between the sixth chip C06 and the first chip C01. Also, the fifth chip C05 may include the second pattern MP2, and the second pattern MP2 and a second wire W2 may be included in a path between the ninth chip C09 and the first chip C01. In some example embodiments, the first pattern MP1 and the second pattern MP2 may be disposed in a wiring layer (for example, a metal layer) of the fifth chip C05.

FIG. 10 is a timing diagram illustrating an operation of a memory device according to example embodiments of the present disclosure. In some example embodiments, the operation of FIG. 10 may be performed by the memory device 50a of FIG. 5A. Hereinafter, FIG. 10 will be described with reference to FIG. 5A.

In some example embodiments, the memory device 50a may be set to one of a first mode M1, a second mode M2, and a third mode M3. For example, the memory device 50a may be set to one of the first to third modes M1 to M3 by the memory controller 11 of FIG. 1. The control circuit included in each of the high-bandwidth memory 51 and the high-density memory 52 may perform an operation according to the set mode. In some example embodiments, at least one of the first to third modes M1 to M3 may be omitted. In FIG. 10, “D_HB” may refer to a data set received or output by the high-bandwidth memory 51, and “D_HD” may refer to a data set received or output by the high-density memory 52.

Referring to FIG. 10, in the first mode M1, the high-bandwidth memory 51 may receive or output data sets, and the high-density memory 52 may not receive or output a data set. For example, the high-bandwidth memory 51 may receive or output each of the first to sixth data sets DQ1 to DQ6. To this end, the data pad set DP of the high-density memory 52 may be floated and may be in a high impedance state in the first mode M1.

In the second mode M2, the high-density memory 52 may receive or output a data set, and the high-bandwidth memory 51 may not receive or output data sets. For example, the high-density memory 52 may receive or output the fifth data set DQ5. To this end, the first to sixth data pad sets DP1 to DP6 of the high-bandwidth memory 51 may be floated and may be in a high impedance state.

In the third mode M3, the high-bandwidth memory 51 and the high-density memory 52 may receive or output data sets. For example, the high-bandwidth memory 51 may receive or output each of the first to fourth data sets DQ1 to DQ4 and the sixth data set DQ6, and the high-density memory 52 may receive or output the fifth data set DQ5. To this end, the fifth data pad set DP5 of the high-bandwidth memory 51 may be floated and may be in a high impedance state.

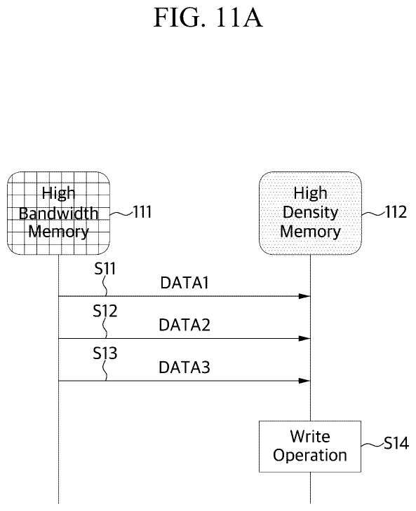

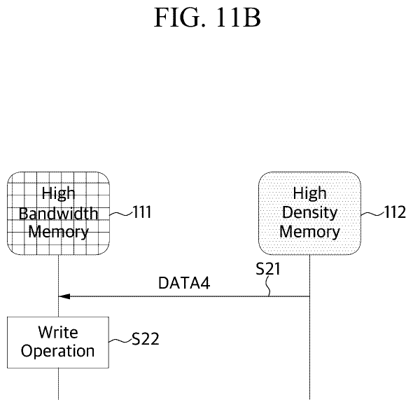

FIGS. 11A and 11B are message flow diagrams illustrating examples of operations of a memory device according to example embodiments of the present disclosure. For example, the message flow diagrams of FIGS. 11A and 11B illustrate examples of operations of a memory device including a high-bandwidth memory 111 including a memory cell storing 1 bit, that is, an SLC, and a high-density memory 112 including a memory cell storing 3 bits, that is, a TLC.

In some example embodiments, data may be transferred between the high-bandwidth memory 111 and the high-density memory 112 within the memory device. For example, as illustrated in FIG. 11A, data stored in the high-bandwidth memory 111 may be stored in the high-density memory 112 in the memory device set to a fourth mode. Also, as illustrated in FIG. 11B, data stored in the high-density memory 112 may be stored in the high-bandwidth memory 111 in the memory device set to a fifth mode.

Referring to FIG. 11A, in operation S11, operation S12, and operation S13, the high-bandwidth memory 111 may sequentially provide first data DATA1, second data DATA2, and third data DATA3 to the high-density memory 112. For example, the first to third data DATA1 to DATA3 may be provided through a data pad set of the high-bandwidth memory 111 and a data pad set of the high-density memory 112 connected to each other. In operation S14, the high-density memory 112 may write the first to third data DATA1 to DATA3. As described above, when the high-bandwidth memory 111 includes the SLC and the high-density memory 112 includes the TLC, the high-density memory 112 may collect the first to third data DATA1 to DATA3 sequentially read from the high-bandwidth memory 111 and program the collected data into TLCs. In some example embodiments, each of the first to third data DATA1 to DATA3 may correspond to a page read from the high-bandwidth memory 111 or a portion of the page.

Referring to FIG. 11B, in operation S21, the high-density memory 112 may provide fourth data DATA4 to the high-bandwidth memory 111. For example, the fourth data DATA4 may be provided through a data pad set of the high-bandwidth memory 111 and a data pad set of the high-density memory 112 connected to each other. In operation S22, the high-bandwidth memory 111 may write the fourth data DATA4. In some example embodiments, the fourth data DATA4 may correspond to a page read from the high-density memory 112 or a portion of the page.

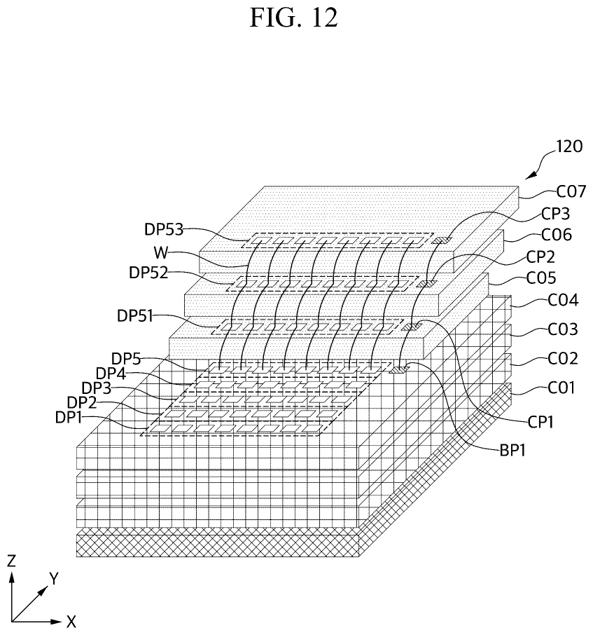

FIG. 12 is a diagram illustrating a device 120 according to example embodiments of the present disclosure. For example, FIG. 12 illustrates the device 120 including a high-bandwidth memory and a high-density memory that share at least one data set, as described above with reference to FIGS. 5A and 5B. In some example embodiments, the high-bandwidth memory and/or the high-density memory may include a number of chips different from those illustrated in FIG. 12. Hereinafter, redundant descriptions will be omitted from descriptions of FIG. 12.

Referring to FIG. 12, the device 120 may include the first to seventh chips C01 to C07 stacked in the Z-axis direction. The first chip C01 may be a base chip or a base die, and the second to seventh chips C02 to C07 may be memory chips. The first chip C01 may be electrically connected to the memory chips and may communicate with the memory chips. In some example embodiments, the device 120 may correspond to the memory device 12 of FIG. 1. For example, the first chip C01 may include a logic circuit and may provide an interface between the outside of the device 120, for example, the memory controller 11 of FIG. 1, and the memory chips. In some example embodiments, the device 120 may correspond to the storage device 10 of FIG. 1, and the first chip C01 may include the memory controller 11 of FIG. 1.

The second to fourth chips C02 to C04 may be disposed above the first chip C01 and may correspond to the high-bandwidth memory. The fifth to seventh chips C05 to C07 may be disposed above the second to fourth chips C02 to C04 and may correspond to the high-density memory. The fourth chip C04 may include the first to fifth data pad sets DP1 to DP5, and the fifth data pad set DP5 may be electrically connected to the data pad sets DP51 to DP53 of the fifth to seventh chips C05 to C07 through the wire W.

In some example embodiments, the high-bandwidth memory may include a bypass pad for providing a clock signal and/or a control signal to the high-density memory. For example, as illustrated in FIG. 12, the fourth chip C04 may include a bypass pad BP1, and the bypass pad BP1 may be electrically connected to control pads CP1, CP2, and CP3 of the fifth to seventh chips C05 to C07 through the wire W. The bypass pad BP1 may be insulated from a circuit of the fourth chip C04, and as a result, the control pads CP1 to CP3 may independently receive a clock signal or a control signal from the first chip C01. In some example embodiments, as described above with reference to FIG. 9B, the control pads CP1 to CP3 may be electrically connected to a bypass pad of the fourth chip C04 through through silicon vias. In some example embodiments, as described above with reference to FIG. 9C, the control pads CP1 to CP3 may be electrically connected to the first chip C01 through a redistribution chip.

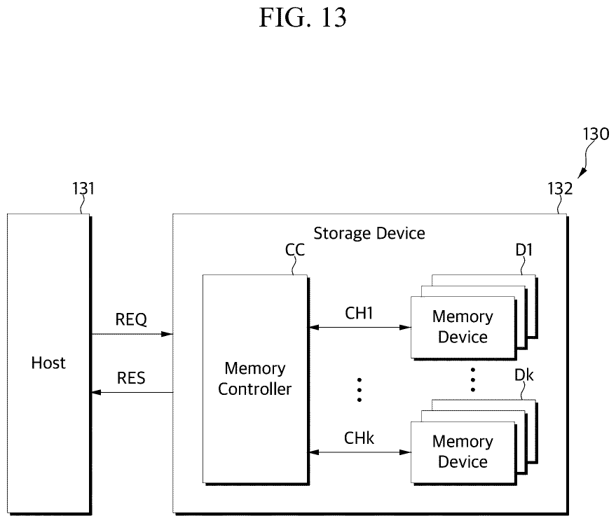

FIG. 13 is a block diagram illustrating a system 130 according to example embodiments of the present disclosure. As illustrated in FIG. 13, the system 130 may include a host 131 and a storage device 132. In some example embodiments, the storage device 132 may be a solid state drive (SSD).

The host 131 may provide a request REQ to the storage device 132 and may receive a response RES from the storage device 132. For example, the request REQ may request data write, and the response RES may indicate completion of the data write. Also, the request REQ may request data read, and the response RES may include the read data.

The storage device 132 may include a memory controller CC and first to k-th memory devices D1 to Dk, where k is a positive integer. The first to k-th memory devices D1 to Dk may communicate with the memory controller CC through first to k-th channels CH1 to CHk. As described above with reference to the drawings, each of the first to k-th memory devices D1 to Dk may include a high-bandwidth memory and a high-density memory. As a result, the storage device 132 may provide high response speed and storage capacity.

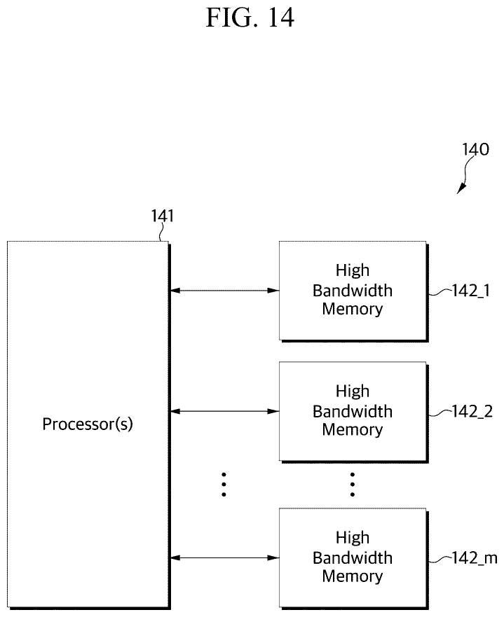

FIG. 14 is a block diagram illustrating a system 140 according to example embodiments of the present disclosure. As illustrated in FIG. 14, the system 140 may include a processor 141 and first to m-th high-bandwidth storages 142_1 to 142_m. In some example embodiments, the system 140 may correspond to a single package, and the processor 141 and the first to m-th high-bandwidth storages 142_1 to 142_m may be mounted on an interposer in the single package. In some example embodiments, the system 140 may correspond to a single module, and packages including the processor 141 and each of the first to m-th high-bandwidth storages 142_1 to 142_m may be mounted on a board. When a high-bandwidth storage includes flash memory, the high-bandwidth storage may be referred to as high bandwidth flash (HBF).

The processor 141 may be any component that processes data. For example, the processor 141 may be a processor that executes software code, a fixed intellectual property (IP) such as a hardware accelerator, or a reconfigurable component such as a field programmable gate array (FPGA). Also, the processor 141 may be a component designed for parallel processing, such as a graphics processing unit (GPU) and a neural processing unit (NPU).

The processor 141 may access the first to m-th high-bandwidth storages 142_1 to 142_m. The processor 141 may store data in the first to m-th high-bandwidth storages 142_1 to 142_m or may read data stored in the first to m-th high-bandwidth storages 142_1 to 142_m. As described above with reference to the drawings, the first to m-th high-bandwidth storages 142_1 to 142_m may include a high-bandwidth memory and a high-density memory and may provide high bandwidth and high capacity. As a result, the first to m-th high-bandwidth storages 142_1 to 142_m may provide high bandwidth as well as high storage capacity to the processor 141.

As described above, example embodiments are disclosed in the drawings and the specification. Herein, particular terms are used to describe example embodiments, but are used to explain the technical idea of the present disclosure and not intended to limit the meaning or scope of the present disclosure set forth in the claims. Therefore, those skilled in the art will understand that various modifications and other equivalent example embodiments may be made therefrom.

What is claimed is:

1. A device comprising:
a first memory chip comprising a plurality of memory planes and a plurality of data pad sets corresponding to the plurality of memory planes, respectively, the plurality of data pad sets comprising a first data pad set; and
a second memory chip comprising a second data pad set electrically connected to the first data pad set,
wherein the plurality of data pad sets include at least one data pad set insulated from the second memory chip.

2. The device of claim 1, wherein:
each of the plurality of memory planes includes a first memory cell configured to store at least one bit, and
the second memory chip includes a second memory cell configured to store more bits than the at least one bit.

3. The device of claim 1, wherein the second memory chip includes through silicon vias electrically connected to pads of the second data pad set, respectively.

4. The device of claim 1, further comprising wires configured to electrically connect pads of the first data pad set to pads of the second data pad set, respectively.

5. The device of claim 1, further comprising a redistribution chip disposed between the first memory chip and the second memory chip,
wherein the redistribution chip includes patterns configured to electrically connect pads of the first data pad set to pads of the second data pad set.

6. The device of claim 1, further comprising:
a third memory chip comprising a third data pad set; and
a frequency boosting interface (FBI) chip comprising a switch set configured to electrically connect the first data pad set to the second data pad set in a first connection mode and to the third data pad set in a second connection mode.

7. The device of claim 1, further comprising a fourth memory chip comprising a fourth data pad set electrically connected to a fifth data pad set of the plurality of data pad sets.

8. The device of claim 1, further comprising a fifth memory chip comprising a plurality of memory planes and a plurality of data pad sets, each data pad set of the plurality of data pad sets corresponding to a respective one of the plurality of memory planes,
wherein each of the plurality of data pad sets of the fifth memory chip is electrically connected to a respective one of the plurality of data pad sets of the first memory chip.

9. The device of claim 1, further comprising a sixth memory chip comprising a sixth data pad set electrically connected to the first data pad set,
wherein the at least one data pad set is insulated from the sixth memory chip.

10. The device of claim 1, wherein:
the first memory chip is configured to:
receive or output data through the plurality of data pad sets in a first mode; and
float the first data pad set in a second mode, and
the second memory chip is configured to:
float the second data pad set in the first mode; and
receive or output data through the second data pad set in the second mode.

11. The device of claim 10, wherein:
the first memory chip is configured to receive or output data through data pad sets of the plurality of data pad sets other than the first data pad set in a third mode, and
the second memory chip is configured to receive or output data through the second data pad set in the third mode.

12. The device of claim 1, wherein:
the first memory chip is configured to sequentially output first data and second data through the first data pad set in a fourth mode, and
in the fourth mode, the second memory chip is configured to receive, from the first memory chip, the second data and data including the second data through the second data pad set and then write the received data.

13. The device of claim 1, wherein:
the second memory chip is configured to output third data through the second data pad set in a fifth mode, and
in the fifth mode, the first memory chip is configured to receive the third data through the first data pad set and write the received third data.

14. The device of claim 1, wherein:
the second memory chip includes a clock pad configured to receive a clock signal, and
the first memory chip further includes a bypass pad electrically connected to the clock pad and insulated from a circuit included in the first memory chip.

15. A device comprising:
a first memory chip comprising a plurality of memory planes and a plurality of data pad sets corresponding to the plurality of memory planes, respectively; and
a second memory chip comprising a first data pad set insulated from the plurality of data pad sets,
wherein:
each of the plurality of memory planes includes a first memory cell configured to store at least one bit, and
the second memory chip includes a second memory cell configured to store more bits than the at least one bit.

16. The device of claim 15, wherein the second memory chip includes through silicon vias electrically connected to pads of the first data pad set, respectively.

17. The device of claim 15, further comprising:
wires electrically connected to pads of the first data pad set, respectively.

18. The device of claim 15, wherein the first memory chip includes a bypass pad set electrically connected to the first data pad set.

19. The device of claim 15, further comprising:
a redistribution chip disposed between the first memory chip and the second memory chip,
wherein the redistribution chip includes a second data pad set electrically connected to the first data pad set.

20. A device comprising:
a first memory chip comprising a plurality of memory planes and a plurality of data pad sets, corresponding to the plurality of memory planes, respectively; and
a second memory chip comprising a second data pad set electrically connected to a first data pad set of the plurality of data pad sets,
wherein:
the first memory chip is configured to:
receive or output data through the plurality of data pad sets in a first mode; and
float the first data pad set in a second mode, and
the second memory chip is configured to:
float the second data pad set in the first mode; and
receive or output data through the second data pad set in the second mode.
